(19) United States
(12) Patent Application Publication
(10) Pub. No.: US 2023/0247848 A1
(43) Pub. Date: Aug. 3, 2023

(54) LIGHT-EMITTING ELEMENT AND DISPLAY DEVICE

(71) Applicant: SHARP KABUSHIKI KAISHA, Sakai City, Osaka (JP)

(72) Inventors: TATSUYA RYOHWA, Sakai City, Osaka (JP); KANAKO NAKATA, Sakai City, Osaka (JP); YUSUKE SAKAKIBARA, Sakai City, Osaka (JP); MAKOTO IZUMI, Sakai City, Osaka (JP)

(21) Appl. No.: 17/928,277

(22) PCT Filed: Jun. 1, 2020
(86) PCT No.: PCT/JP2020/021664

§ 371 Date: Nov. 28, 2022

(51) Int. Cl. H10K 50/115; H10K 50/16; H10K 59/38

(52) U.S. Cl. CPC H10K 50/115; H10K 50/16; H10K 59/38

(57) ABSTRACT

A light-emitting layer included in a light-emitting element according to the disclosure contains a plurality of red quantum dots that emit red light, a plurality of green quantum dots that emit green light, and a plurality of blue quantum dots that emit blue light. The surface-to-surface distance between the red quantum dots adjacent to each other is longer than the surface-to-surface distance between the green quantum dots adjacent to each other, and the surface-to-surface distance between the green quantum dots adjacent to each other is longer than the surface-to-surface distance between the blue quantum dots adjacent to each other.

### TECHNICAL FIELD

The present invention relates to a light-emitting element and a display device.

### BACKGROUND ART

Various flat-panel displays have been recently developed, and particular attention has been directed to display devices that include quantum-dot light-emitting diodes (QLEDs) as electric-field light-emitting elements.

Patent Literature 1 discloses two configurations for achieving a light-emitting element that emits white light. One the configurations is an anode and cathode between which the following are disposed in series: a red light-emitting layer containing red quantum dots that emit red light, an electric-charge generating layer, a green light-emitting layer containing green quantum dots that emit green light, an electric-charge generating layer, and a blue light-emitting layer containing blue quantum dots that emit blue light. The other configuration is a single light-emitting layer within which red quantum dots, green quantum dots, and blue quantum dots are mixed.

### CITATION LIST

### Patent Literature

Patent Literature 1: Japanese Unexamined Patent Application Publication No. 2014-78381 (published on May 1, 2014)

### SUMMARY OF INVENTION

### Technical Problem

A quantum dot with a longer wavelength of emitted light has a lower lowest unoccupied molecular orbital (LUMO). Moreover, a quantum dot with a lower LUMO undergoes electron injection into its unoccupied orbitals more easily. There is thus a large difference in electron injection efficiency between quantum dots with mutually different wavelengths of emitted light. As a result, uniform white-light emission is difficult to obtain.

The present invention has been made in view of the above problem and aims to facilitate obtaining uniform white-light emission

### Solution to Problem

To solve the above problem, a light-emitting element according to one aspect of the present invention includes the following: a first electrode; a second electrode; and a light-emitting layer provided between the first electrode and the second electrode, wherein the light-emitting layer contains a plurality of first quantum dots configured to emit light of a first color, a plurality of second quantum dots configured to emit light of a second color having a shorter wavelength than the light of the first color, and a plurality of third quantum dots configured to emit light of a third color having a shorter wavelength than the light of the second color, the surface-to-surface distance between first quantum dots adjacent to each other belonging to the plurality of first quantum dots is longer than the surface-to-surface distance between second quantum dots adjacent to each other belonging to the plurality of second quantum dots, and the surface-to-surface distance between second quantum dots adjacent to each other belonging to the plurality of second quantum dots is longer than the surface-to-surface distance between third quantum dots adjacent to each other belonging to the plurality of third quantum dots.

To solve the above problem, a light-emitting element according to one aspect of the present invention includes the following: a first electrode; a second electrode; and a light-emitting layer provided between the first electrode and the second electrode, wherein the light-emitting layer contains a plurality of first quantum dots configured to emit light of a first color, a plurality of second quantum dots configured to emit light of a second color having a shorter wavelength than the light of the first color, and a plurality of third quantum dots configured to emit light of a third color having a shorter wavelength than the light of the second color, the plurality of first quantum dots are each modified by a first ligand, the plurality of second quantum dots are each modified by a second ligand, the plurality of third quantum dots are each modified by a third ligand, the amount of substance of the first ligand modifying a single first quantum dot belonging to the plurality of first quantum dots is larger than the amount of substance of the second ligand modifying a single second quantum dot belonging to the plurality of second quantum dots, and the amount of substance of the second ligand modifying the single second quantum dot is larger than the amount of substance of the third ligand modifying a single third quantum dot belonging to the plurality of third quantum dots.

To solve the above problem, a light-emitting element according to one aspect of the present invention includes the following: a first electrode; a second electrode; and a light-emitting layer provided between the first electrode and the second electrode, wherein the light-emitting layer contains a plurality of first quantum dots configured to emit light of a first color, a plurality of second quantum dots configured to emit light of a second color having a shorter wavelength than the light of the first color, and a plurality of third quantum dots configured to emit light of a third color having a shorter wavelength than the light of the second color, the plurality of first quantum dots are each modified by a first ligand, the plurality of second quantum dots are each modified by a second ligand, the plurality of third quantum dots are each modified by a third ligand, the molecular length of the first ligand is longer than the molecular length of the second ligand, and the molecular length of the second ligand is longer than the molecular length of the third ligand.

### Advantageous Effect of Invention

The aspects of the present invention can facilitate obtaining uniform white-light emission.

### BRIEF DESCRIPTION OF DRAWINGS

FIG. 1 is a flowchart showing an example method for manufacturing a display device.

FIG. 2 is a schematic sectional view of the configuration of a display region of the display device.

FIG. 3 is a schematic sectional view of an example configuration of an active layer of the display device shown in FIG. 2.

FIG. 4 is a schematic diagram illustrating the surface-to-surface distance between quantum dots contained in a light-emitting layer of a display device in a comparative example.

FIG. 5 is a schematic sectional view of the configuration of a light-emitting layer according to one embodiment of the present invention.

FIG. 6 is a schematic diagram illustrating the surface-to-surface distance between quantum dots contained in the light-emitting layer shown in FIG. 5.

FIG. 7 is a schematic sectional view of the configuration in a modification of the light-emitting layer shown in FIG. 5.

FIG. 8 is a schematic sectional view of the configuration of a light-emitting layer according to another embodiment of the present invention.

FIG. 9 is a schematic diagram of the surface-to-surface distance between quantum dots contained in the light-emitting layer shown in FIG. 8.

FIG. 10 is a schematic sectional view of the configuration in a modification of the light-emitting layer shown in FIG. 8.

FIG. 11 is a schematic diagram of the configurations in modifications of a red ligand, a green ligand and a blue ligand modifying the quantum dots contained in the light-emitting layer shown in FIG. 8.

### DESCRIPTION OF EMBODIMENTS

The term “in the same layer” hereinafter refers to that one layer is formed in the same process step (film formation step) as another layer, the term “under” hereinafter refers to that one layer is formed in a process step anterior to a process step of forming a comparative layer, and the term “over” hereinafter refers to that one layer is formed in a process step posterior to a process step of forming a comparative layer.

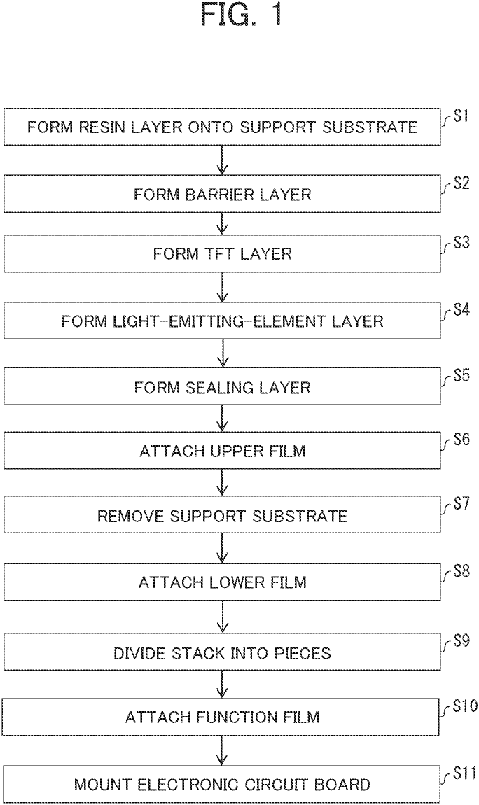

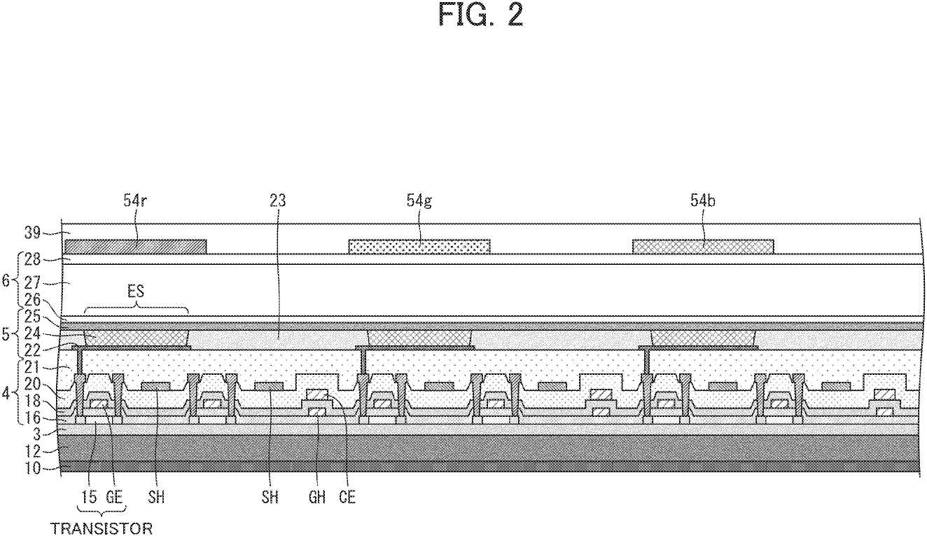

FIG. 1 is a flowchart showing an example method for manufacturing a display device. FIG. 2 is a sectional view of the configuration of a display region of a display device 2.

A flexible display device is manufactured through the following process steps, as illustrated in FIGS. 1 and 2. The first step (Step S1) is forming a resin layer 12 onto a light-transparency support substrate (e.g., mother glass substrate). The next (Step S2) is forming a barrier layer 3. The next (Step S3) is forming a TFT layer 4. The next (Step S4) is forming a top-emission light-emitting-element layer 5. The next (Step S5) is forming a sealing layer 6. The next (Step S6) is attaching an upper film onto the sealing layer 6.

The next (Step S7) is removing the support substrate from the resin layer 12 through laser light irradiation or other methods. The next (Step S8) is attaching a lower film 10 onto the lower surface of the resin layer 12 The next (Step S9) is dividing a stack of the lower film 10, resin layer 12, barrier layer 3, TFT layer 4, light-emitting-element layer 5 and sealing layer 6 into a plurality of pieces. The next (Step S10) is attaching a function film 39 onto the obtained pieces. The next (Step S11) is mounting electronic circuit boards (e.g., an IC chip and an FPC) onto a part (terminal section) of the outside (a non-display region or frame region) of the display region with a plurality of subpixels formed therein It is noted that Steps S1 through S11 are performed by an apparatus (including a film formation apparatus that performs Steps S1 through S5) that manufactures a display device.

An example of the material of the resin layer 12 is polyimide. The resin layer 12 can be replaced with two resin films (e.g., polyimide films) and an inorganic insulating film interposed between them.

The barrier layer 3 protects the TFT layer 4 and light-emitting-element layer 5 from intrusion of foreign substances, including water and oxygen, and can be composed of, for instance, a silicon oxide film, a silicon nitride film, or a silicon oxide nitride film, all of which are formed through CVD, or a laminated film of these materials.

The TFT layer 4 includes the following: a semiconductor film 15; an inorganic insulating film 16 (gate insulating film) over the semiconductor film 15; a gate electrode GE and a gate wire GH over the inorganic insulating film 16; an inorganic insulating film 18 over the gate electrode GE and gate wire GH; a capacitive electrode CE over the inorganic insulating film 18; an inorganic insulating film 20 over the capacitive electrode CE; a source wire over the inorganic insulating film 20; and a flattening film 21 (interlayer insulating film) over the source wire SH.

The semiconductor film 15 is composed of, for instance, a low-temperature polysilicon (LTPS) material or an oxide semiconductor (e.g., an In-Ga-Zn-O semiconductor) and constitutes, together with the gate electrode GE, a transistor (TFT). Although FIG. 2 illustrates a transistor of top-gate structure, the transistor may be of bottom-gate structure.

The gate electrode GE, the gate wire GH, the capacitive electrode CE, and the source wire SH are composed of, for instance, a monolayer film or a laminated film containing at least one of aluminum, tungsten, molybdenum, tantalum, chromium, titanium and copper. The TFT layer 4 in FIG. 2 includes one semiconductor layer and three metal layers

The inorganic insulating films 16, 18, and 20 can be composed of, for instance, a silicon oxide (SiOx) film or a silicon nitride (SiNx) film, both of which are formed through CVD, or can be composed of, for instance, a laminate of these films. The flattening film 21 can be made of an organic material that can be applied, such as polyimide or acrylic.

The light-emitting-element layer 5 includes the following: an anode 22 (positive electrode) over the flattening film 21; an insulating edge cover 23 covering the edge of the anode 22; an active layer 24 disposed over the edge cover 23 and that emits electroluminescence (EL); and a cathode 25 (negative electrode) over the active layer 24. The edge cover 23 is formed by, for instance, applying an organic material, such as polyimide or acrylic, followed by patterning through photolithography.

Each subpixel includes the anode 22 in the form of an island, the active layer 24, and the cathode 25, which form a light-emitting element ES (electric-field light-emitting element) in the light-emitting-element layer 5; moreover, a subpixel circuit that controls the light-emitting element ES is formed in the TFT layer 4.

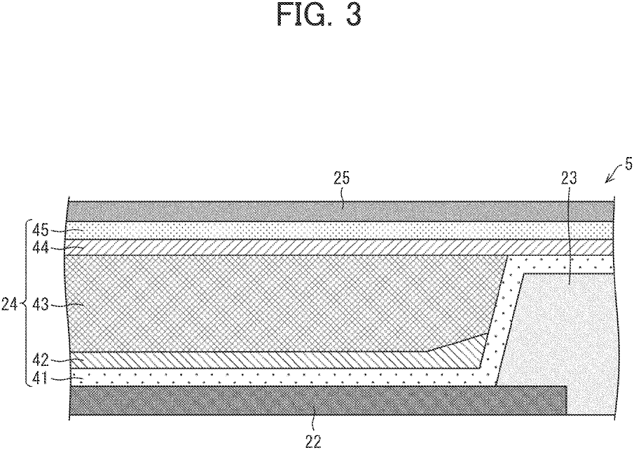

The active layer 24 is composed of, for instance, a stack of, in sequence from the bottom, a hole injection layer 41, a hole transport layer 42, a light-emitting layer 43, an electron transport layer 44, and an electron injection layer 45, as illustrated in FIG. 3. The light-emitting layer 43 is formed in the form of an island in the openings of the edge cover 23 (for each subpixel) through an evaporation method or an ink-jet method. The other layers 41, 42, 44, and 45 are formed in the form of an island or in a flat manner (common layers). Moreover, in a possible configuration, one or more of the hole injection layer 41, hole transport layer 42, electron transport layer 44 and electron injection layer 45 are not formed.

For the light-emitting layer of a QLED, the light-emitting layer 43 can be formed in the form of an island (corresponding to a single subpixel) by, for instance, applying a solvent with quantum dots dispersed therein through an ink-jet method.

The anode 22 is a reflective electrode that is composed of, for instance, a stack of indium tin oxide (ITO) and silver (Ag) or a stack of ITO and Ag-containing alloy or is composed of, for instance, a Ag- or Al-containing material and has light reflectivity. The cathode (negative electrode) 25 is a transparent electrode that is composed of a light-transparency conductor, including a thin film of Ag, Au, Pt, Ni or Ir, a thin film of MgAg alloy, an ITO, and an indium zinc oxide (IZO). When the display device is a bottom-emission type rather than a top-emission type, the lower film 10 and the resin layer 12 are transparent to light, the anode 22 is a transparent electrode, and the cathode 25 is a reflective electrode.

In each light-emitting element ES, a drive current between the anode 22 and the cathode 25 causes holes and electrons to rejoin within the light-emitting layer 43 to thus generate excitons, and the excitons emit light (fluorescent light) in the process of transition from the conduction band of the quantum dots to the valence band of the same.

The sealing layer 6 is transparent to light and includes an inorganic sealing film 26 covering the cathode 25, an organic buffer layer 27 over the inorganic sealing film 26, and an inorganic sealing film 28 over the organic buffer layer 27. The sealing layer 6, covering the light-emitting-element layer 5, prevents foreign substances, such as water and oxygen, from intrusion into the light-emitting-element layer 5.

The inorganic sealing film 26 and the inorganic sealing film 28 are inorganic insulating films and can be composed of, for instance, a silicon oxide film, a silicon nitride film, or a silicon oxide nitride film, all of which are formed through CVD, or the films can be composed of, for instance, a laminate of these films. The organic buffer layer 27 is a light-transparency organic film having a flattening effect and can be made of an organic material that can be applied, such as acrylic. The organic buffer layer 27 can be formed through ink jet application for instance; in this case, a bank for stopping droplets may be provided in the non-display region.

The lower film 10 is, for instance, a PET film that is attached to the lower surface of the resin layer 12 after the removal of the support substrate, so that a highly flexible display device is achieved. The function film 39 has at least one of, for instance, the function of optical compensation, the function of touch sensing and the function of protection.

The foregoing has described a flexible display device. For manufacturing a non-flexible display device, forming a resin layer, replacing a base, and other process steps are typically unnecessary; accordingly, for instance, the stacking step, i.e., Steps S2 through S5, is performed on a glass substrate, followed by Step S9. Moreover, for manufacturing a non-flexible display device, a light-transparency sealing member may be bonded with a sealing adhesive under a nitrogen atmosphere instead of or in addition to the formation of the sealing layer 6. Such a light-transparency sealing member can be formed of glass, plastic and other materials and is preferably in the form of a recess.

One embodiment of the present invention is directed particularly to the light-emitting layer 43 of the active layer 24 among the foregoing components of the display device.

### Comparative Example

### Configuration

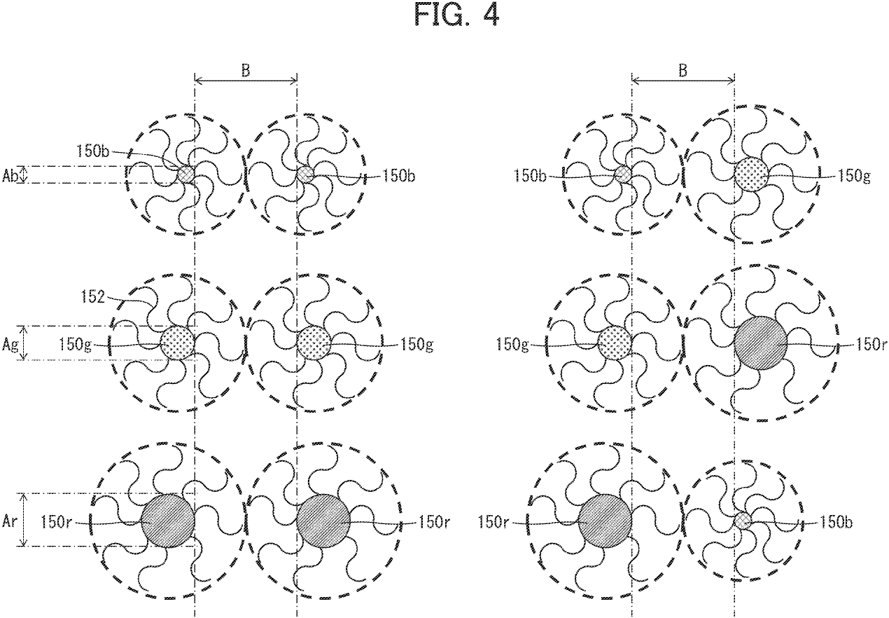

FIG. 4 is a schematic diagram illustrating the surface-to-surface distance, B, between quantum dots 150 contained in a light-emitting layer of a display device in a comparative example.

The light-emitting layer in the comparative example includes a plurality of red quantum dots 150r that emit red light, a plurality of green quantum dots 150g that emit green light, and a plurality of blue quantum dots 150b that emit blue light. The Description defines each quantum dot as a quantum dot 150 when the red quantum dots 150r, the green quantum dots 150g, and the blue quantum dots 150b are referred comprehensively and when any of the red quantum dots 150r, the green quantum dots 150g, and the blue quantum dots 150b is referred to.

A ligand 152 modifying each red quantum dot 150r, a ligand 152 modifying each green quantum dot 150g, and a ligand 152 modifying each blue quantum dot 150b are identical to each other. Furthermore, these ligands satisfy a relationship expressed by Expression (1) below.

$$\begin{matrix}\text{The amount of substance of the ligand 152 modifying a single red} \\ \text{quantum dot 150r = the amount of substance of the ligand 152} \\ \text{modifying a single green quantum dot 150g = the amount of} \\ \text{substance of the ligand 152 modifying a single blue quantum dot} \\ \text{150b}\end{matrix}$$

### Formation Method

The light-emitting layer in the comparative example is formed through process steps described below.

The first process step is putting the red quantum dots 150r, the green quantum dots 150g, and the blue quantum dots 150b into a single solution and stirring them sufficiently. The next is applying the solution with the quantum dots 150 dispersed therein onto a hole transport layer (or onto a hole injection layer or an anode).

### Crystal Size

The crystal size of the red quantum dots 150r, the crystal size of the green quantum dots 150g, and the crystal size of the blue quantum dots 150b are different from each other. As well known, the wavelength of emitted light and crystal size are in a substantially proportional relationship. Accordingly, their crystal sizes satisfy a relationship expressed by Expression (2) below.

$$\begin{matrix}\text{The crystal size, Ar, of the red quantum dots 150r > the crystal size,} \\ \text{Ag, of the green quantum dots 150g > the crystal size, Ab, of the} \\ \text{blue quantum dots 150b}\end{matrix}$$

That is, the crystal size Ar of the red quantum dots 150r is larger than the crystal size Ag of the green quantum dots 150g, and the crystal size Ag of the green quantum dots 150g is larger than the crystal size Ab of the blue quantum dots 150b.

### Surface-to-Surface Distance

The density of the quantum dots 150 dispersed within the solution is high; hence, the surface-to-surface distance between the quantum dots 150 in the light-emitting layer in the comparative example is determined by the ligands 152 modifying the quantum dots 150. Here, the ligands 152 modifying the quantum dots 150 are identical to each other and satisfy the foregoing relationship expressed by Expression (1). Accordingly, their surface-to-surface distances satisfy a relationship expressed by Expression (3) below, as illustrated in FIG. 4.

$$\begin{matrix}\text{The surface-to-surface distance, B, between the red quantum dots} \\ \text{150r = the surface-to-surface distance B between the green} \\ \text{quantum dots 150g = the surface-to-surface distance B between the} \\ \text{blue quantum dots 150b = the surface-to-surface distance B between} \\ \text{one of the red quantum dots 150r and one of the green quantum dots} \\ \text{150g = the surface-to-surface distance B between one of the red} \\ \text{quantum dots 150r and one of the blue quantum dots 150b = the} \\ \text{surface-to-surface distance B between one of the green quantum} \\ \text{dots 150g and one of the blue quantum dots 150b}\end{matrix}$$

That is, the surface-to-surface distance B between the quantum dots 150 adjacent to each other stands at a common value irrespective of which of the red quantum dot 150r, green quantum dot 150g and blue quantum dot 150b each quantum dot 150 is.

### Mobility

Electrons move between the quantum dots 150 through hopping conduction. Electron mobility depends on, as indicated by Expression (4) below, the surface-to-surface distance B between the quantum dots 150, the electron confinement factor, a, of the quantum dots 150, activation energy Ea, the Boltzmann constant kb, and temperature T.

$$\text{Mobility} ∝ \text{exp} \left(- 2 \text{aB} \text{−} \text{Ea} / \text{kbT}\right)$$

Here, the confinement factor a, the activation energy Ea, the Boltzmann constant kb, and the temperature T stand at a common value. Moreover, the foregoing relationship expressed by Expression (3) is satisfied; thus, the surface-to-surface distances B also stand at a common value.

Accordingly, the electron mobility of the red quantum dots 150r, the electron mobility of the green quantum dots 150g, and the electron mobility of the blue quantum dots 150b stand at a common value in the comparative example.

### First Embodiment

The following details one embodiment of the present invention with reference to the drawings. Shape, size and relative arrangement in the drawings are mere illustrative, and the scope of the present invention should not be restrictively interpreted by them.

### Configuration

As illustrated in FIG. 2, a display device 2 according to this embodiment has the following: an anode 22 (first electrode); a cathode 25 (second electrode); an insulating edge cover 23 (edge cover film) formed so as to cover the edge of the anode 22; an active layer 24 provided between the anode 22 and the cathode 25; and a function film 39. The display device 2 according to this embodiment includes a plurality of light-emitting elements ES.

The anode 22 is provided in the form of an island for each light-emitting element ES. In contrast, the cathode 25 is provided in common in the plurality of light-emitting elements ES and is preferably provided in a flat manner. Alternatively, the anode 22 may be provided in common in the plurality of light-emitting elements ES, and the cathode 25 may be provided for each light-emitting element ES.

The function film 39 includes, for each light-emitting element ES, a red color filter 54r that allows red light to pass, a green color filter 54g that allows green light to pass, and a blue color filter 54b that allows blue light to pass.

As illustrated in FIG. 3, the active layer 24 according to this embodiment has at least a light-emitting layer 43 and has, as necessary, one or more of a hole injection layer 41, a hole transport layer 42 (electric-charge transport layer), an electron transport layer 44 (electric-charge transport layer) and an electron injection layer 45. When provided, the hole injection layer 41, the hole transport layer 42, the electron transport layer 44, and the electron injection layer 45 are each preferably provided in common in the plurality of light-emitting elements ES and are each more desirably provided in common in a flat manner.

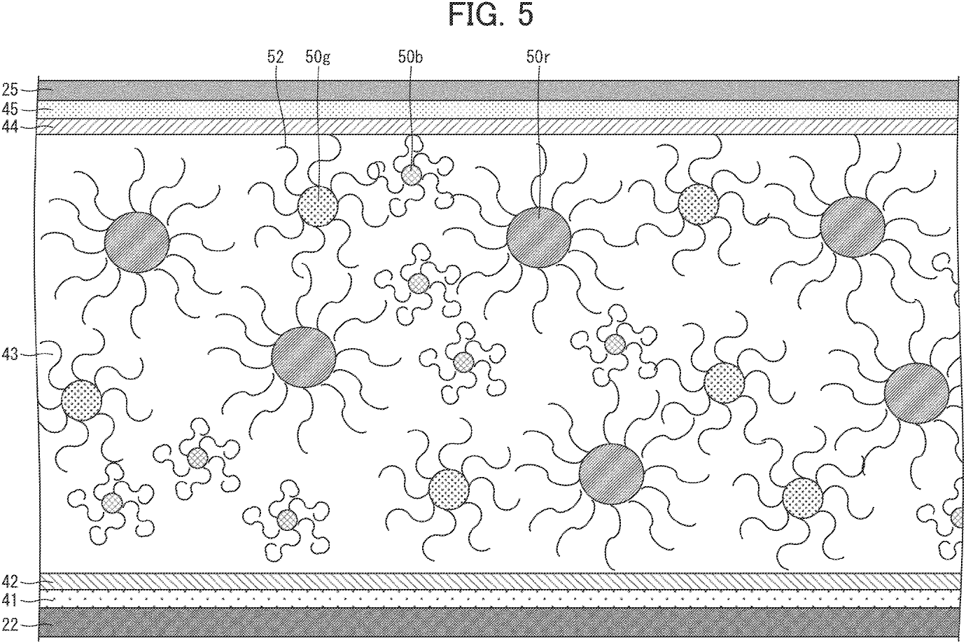

FIG. 5 is a schematic sectional view of the configuration of the light-emitting layer 43 according to this embodiment.

As illustrated in FIG. 5, the light-emitting layer 43 in this embodiment includes the following: a plurality of red quantum dots 50r (first quantum dots) that emit red (first color) light; a plurality of green quantum dots 50g (second quantum dots) that emit green (second color) light having a shorter wavelength than red light; and a plurality of blue quantum dots 50b (third quantum dots) that emit blue (third color) light having a shorter wavelength than green light. Mixture of red, green and blue enables the light-emitting elements ES to emit white light. Hereinafter, each of the red quantum dots 50r, the green quantum dots 50g, and the blue quantum dots 50b will be referred to as a quantum dot 50 when they are referred comprehensively and when any of the red quantum dots 50r, the green quantum dots 50g, and the blue quantum dots 50b is referred to.

The quantum dots 50 each preferably contain at least one of CdS, CdSe, CdTe, ZnS, ZnSe, ZnTe, InN, InP, InAs, InSb, AlP, AlS, AlAs, AlSb, GaN, GaP, GaAs, GaSb, PbS, PbSe, Si, Ge, MgS, MgSe, and MgTe. The quantum dots 50 may or may not be of core-shell structure. The composition of the red quantum dots 50r, the composition of the green quantum dots 50g, and the composition of the blue quantum dots 50b may be identical to or different from each other.

The quantum dots 50 are each modified by a ligand 52, as illustrated in FIG. 5. The ligands 52 (first ligands) modifying the red quantum dots 50r, the ligands 52 (second ligands) modifying the green quantum dots 50g, and the ligands 52 (third ligands) modifying the blue quantum dots 50b are compounds identical to each other. In the Description, that the ligands 52 are identical compounds means that the ligands 52 are expressed by the same rational formula, and furthermore, their structural isomers except the enantiomers are distinguished. The enantiomers are not distinguished.

Each ligand 52 is an organic compound that is in the form of a long chain and is insulating. Each ligand 52 is, but not limited to, an organic compound that has a linear alkyl group and an amine group. The linear alkyl groups of the ligands 52 preferably have 2 or more and 30 or less carbon atoms. The molecular length of the ligands 52 ranges from 0.1 to 10 nm and preferably ranges from 1 to 5 nm.

The amount of the ligand 52 modifying each quantum dot 50 is more than adequate for avoiding deactivation of the quantum dot 50. Furthermore, the amount of the ligand 52 satisfies a relationship expressed by Expression (5) below.

$$\begin{matrix}\text{The amount of substance of the ligand 52 modifying a single red} \\ \text{quantum dot 50r > the amount of substance of the ligand 52} \\ \text{modifying a single green quatnum dot 50g > the amount of} \\ \text{substance of the ligand 52 modifying a single blue quantum dot 50b}\end{matrix}$$

That is, the amount of substance of the ligand 52 modifying a single red quantum dot 50r is larger than the amount of substance of the ligand 52 modifying a single green quantum dot 50g, and the amount of substance of the ligand 52 modifying a single green quantum dot 50g is larger than the amount of substance of the ligand 52 modifying a single blue quantum dot 50b.

The ligands 52 function as an obstacle that physically hinders approaches of the quantum dots 50 to each other, and this function enhances along with increase in the amount of the ligand 52 modifying a single quantum dot 50 and along with increase in the molecular length of each ligand 52. Moreover, the density of the quantum dots 50 dispersed within a solution is high; hence, the surface-to-surface distance between the quantum dots 50 in the light-emitting layer 43 is determined by the ligands 52 modifying the quantum dots 50.

### Formation Method

The light-emitting layer 43 in this embodiment is formed through process steps described below.

The first process step is modifying each of the red quantum dots 50r, green quantum dots 50g and blue quantum dots 50b with the ligand 52 individually in such a manner that the foregoing relationship expressed in Expression (5) is satisfied. The amount of substance of the ligand 52 that is to modify each of the red quantum dots 50r, green quantum dots 50g and blue quantum dots 50b can be regulated by regulating the amount of the ligand 52 that is to be added to the solution with the individual quantum dots 50 dispersed therein.

The next is putting the modified red quantum dots 50r, the modified green quantum dots 50g, and the modified blue quantum dots 50b sequentially or simultaneously into a single solution and stirring them sufficiently. As a result of this stirring, the quantum dots 50 are mixed with each other and are dispersed within the solution, so as to be distributed uniformly in a macroscopic view and to be distributed randomly in a microscopic view.

The next is applying the solution with the quantum dots 50 dispersed therein onto the hole transport layer 42 (or onto the hole injection layer 41 or the anode 22). Accordingly, the red quantum dots 50r, the green quantum dots 50g, and the blue quantum dots 50b are mixed with each other in the light-emitting layer 43 in this embodiment so as to be distributed uniformly in a macroscopic view and to be distributed randomly in a microscopic view, as illustrated in FIG. 5.

The microscopic random distribution of the quantum dots 50 does not substantially affect the emission of the light-emitting elements ES. This is because that the edge cover 23 avoids electric field concentration, thus applying a uniform electric field to the light-emitting layer 43. The microscopic random distribution of the quantum dots 50 produces a microscopic imbalance, for instance, a micro region provided with a large number of green quantum dots 50g and a micro region provided with a small number of green quantum dots 50g. Since the electric field is uniform, the efficiency of electron injection into the green quantum dots 50g is the same in both micro regions. As a result, influences over light emission exerted by both micro regions (specifically, an influence under which a green component is strengthened by the micro region provided with a large number of green quantum dots 50g, and an influence under which a green component is weakened by the micro region provided with a small number of green quantum dots 50g) cancel each other out. It may be thus understood that the red quantum dots 50r, the green quantum dots 50g, and the blue quantum dots 50b are mixed with each other so as to be distributed uniformly.

### Surface-to-Surface Distance

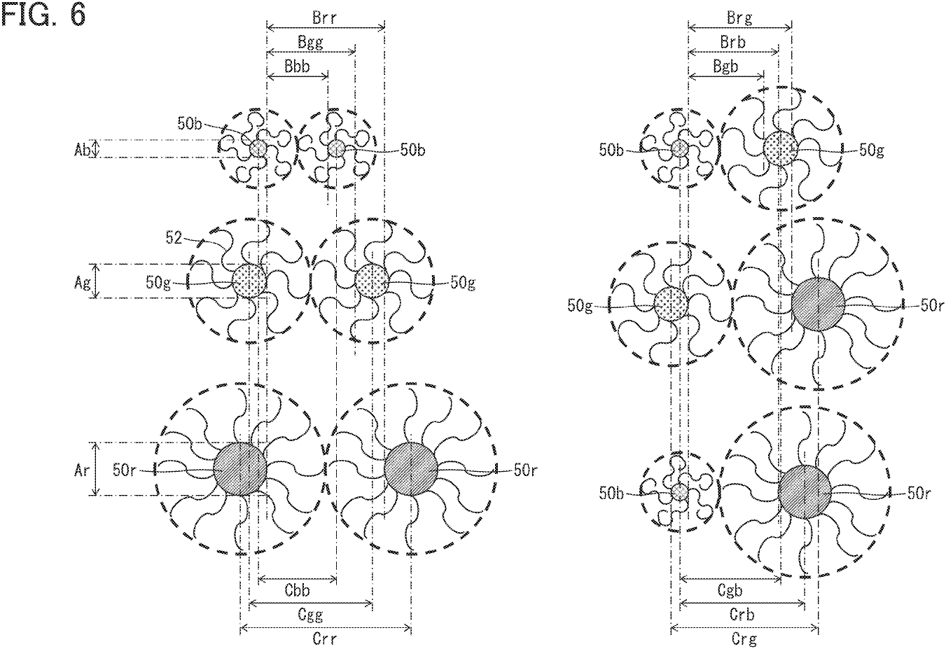

FIG. 6 is a schematic diagram illustrating surface-to-surface distances Brr, Bgg, Bbb, Brg, Bgb, and Brb between the quantum dots 50 contained in the light-emitting layer 43 shown in FIG. 5. The surface-to-surface distance between two adjacent quantum dots 50 in the Description means a designed value or nominal value of the surface-to-surface distance between the two quantum dots 50 or means a value that is obtained by subtracting a half value of the sum of the crystal sizes of the two quantum dots 50 from the center-to-center distance between the two quantum dots 50. To be specific, relationships below are established.

$$\begin{matrix}\text{Brr} \text{=} \text{Crr} - \left(\text{Ar + Ar}\right) / 2 = \text{Crr} \text{−} \text{Ar} \\ \text{Bgg} \text{=} \text{Cgg} \text{−} \left(\text{Ag} \text{+ Ag}\right) / 2 = \text{Cgg} \text{−} \text{Ag} \\ \text{Bbb} \text{=} \text{Cbb} \text{−} \left(\text{Ab} \text{+ Ab}\right) / 2 = \text{Cbb} \text{−} \text{Ab} \\ \text{Brg} \text{=} \text{Crg} \text{−} \left(\text{Ar} \text{+} \text{Ag}\right) / 2 \\ \text{Brb} \text{=} \text{Crb} \text{−} \left(\text{Ar} \text{+} \text{Ab}\right) / 2 \\ \text{Bgb} \text{=} \text{Cgb} \text{−} \left(\text{Ag} \text{+} \text{Ab}\right) / 2\end{matrix}$$

Here, Brr denotes the surface-to-surface distance between red quantum dots 50r adjacent to each other, Bgg denotes the surface-to-surface distance between green quantum dots 50g adjacent to each other, Bbb denotes the surface-to-surface distance between blue quantum dots 50b adjacent to each other, Brg denotes the surface-to-surface distance between a red quantum dot 50r and a green quantum dot 50g adjacent to each other, Brb denotes the surface-to-surface distance between a red quantum dot 50r and a blue quantum dot 50b adjacent to each other, and Bgb denotes the surface-to-surface distance between a green quantum dot 50g and a blue quantum dot 50b adjacent to each other. Moreover, Crr denotes the center-to-center distance between the red quantum dots 50r adjacent to each other, Cgg denotes the center-to-center distance between the green quantum dots 50g adjacent to each other, Cbb denotes the center-to-center distance between the blue quantum dots 50b adjacent to each other, Crg denotes the center-to-center distance between the red quantum dot 50r and the green quantum dot 50g adjacent to each other, Crb denotes the center-to-center distance between the red quantum dot 50r and the blue quantum dot 50b adjacent to each other, and Cgb denotes the center-to-center distance between the green quantum dot 50g and the blue quantum dot 50b adjacent to each other.

The center-to-center distance between two adjacent quantum dots 50 in the Description means a designed value or nominal value of the center-to-center distance between the two quantum dots 50 or means a median value of the center-to-center distance between the two quantum dots 50 measured through a dynamic light scattering method Moreover, the crystal size of the quantum dots 50 means a designed value or nominal value of the particle diameter of the quantum dots or means a median value of the particle diameter of the quantum dots measured through the dynamic light scattering method.

As earlier described, the function where the ligands 52 physically hinder approaches of the quantum dots 50 to each other enhances along with increase in the amount of the ligand 52 modifying a single quantum dot 50. As also earlier described, the surface-to-surface distance between the quantum dots 50 in the light-emitting layer 43 is determined by the ligands 52 modifying the quantum dots 50. Accordingly, the foregoing relationship expressed by Expression (5) is satisfied, and as illustrated in FIG. 6, relationships expressed by Expression (6) and Expression (7) below are satisfied.

$$\text{Brr > Bgg > Bbb} …$$

$$\text{Brg > Brb > Bgb} …$$

That is, the surface-to-surface distance Brr between the red quantum dots 50r adjacent to each other is longer than the surface-to-surface distance Bgg between the green quantum dots 50g adjacent to each other, and the surface-to-surface distance Bgg between the green quantum dots 50g adjacent to each other is longer than the surface-to-surface distance Bbb between the blue quantum dots 50b adjacent to each other. Moreover, the surface-to-surface distance Brg between the red quantum dot 50r and the green quantum dot 50g adjacent to each other is longer than the surface-to-surface distance Brb between the red quantum dot 50r and the blue quantum dot 50b adjacent to each other, and the surface-to-surface distance Brb between the red quantum dot 50r and the blue quantum dot 50b adjacent to each other is longer than the surface-to-surface distance Bgb between the green quantum dot 50g and the blue quantum dot 50b adjacent to each other

Simultaneously, relationships expressed by Expressions (8), (9), and (10) below are satisfied as well.

$$\text{Brg = Brr} / 2 + \text{Bgg} / 2$$

$$\text{Brb = Brr} / 2 + \text{Bbb} / 2$$

$$\text{Bgb} \text{=} \text{Bgg} / 2 + \text{Bbb} / 2$$

This is because that Brr / 2 corresponds to the thickness of the ligand 52 in the red quantum dot 50r, that Bgg / 2 corresponds to the thickness of the ligand 52 in the green quantum dot 50g, and that Bbb / 2 corresponds to the thickness of the ligand 52 in the blue quantum dot 50b. The thickness of the ligand 52 in each quantum dot 50 relates only to which of the red quantum dot 50r, green quantum dot 50g and blue quantum dot 50b the quantum dot 50 is.

### Expected Value of Surface-to-Surface Distance

Next, the relationship between an expected value Dr of the surface-to-surface distance between the red quantum dot 50r and the adjacent quantum dot 50 (any of the red quantum dot 50r, green quantum dot 50g and blue quantum dot 50b may be used), an expected value Dg of the surface-to-surface distance between the green quantum dot 50g and the adjacent quantum dot 50 (any of the red quantum dot 50r, green quantum dot 50g and blue quantum dot 50b may be used), and an expected value Db of the surface-to-surface distance between the blue quantum dot 50b and the adjacent quantum dot 50 (any of the red quantum dot 50r, green quantum dot 50g and blue quantum dot 50b may be used) will be determined.

The content ratio of the red quantum dots 50r, the content ratio of the green quantum dots 50g, and the content ratio of the blue quantum dots 50b in the light-emitting layer 43 will be respectively denoted by Fr, Fg, and Fb. Here, Fr + Fg + Fb = 1 as well as Fr > 0, Fg > 0, and Fb > 0 are satisfied. The quantum dots 50 are mixed to each other so as to be distributed uniformly, as earlier described. Furthermore, the light-emitting layer 43 contains many quantum dots 50; accordingly, the following approximations can be made: the number of red quantum dots 50r - 1 ≈ the number of red quantum dots 50r, the number of green quantum dots 50g -1 ≈ the number of green quantum dots 50g, and the number of blue quantum dots 50b -1 ≈ the number of blue quantum dots 50b. Hence, the probability that the quantum dot 50 adjacent to the red quantum dot 50r is a red quantum dot 50r, the probability that the quantum dot 50 adjacent to the red quantum dot 50r is a green quantum dot 50g, and the probability that the quantum dot 50 adjacent to the red quantum dot 50r is a blue quantum dot 50b are respectively Fr, Fg, and Fb. Accordingly, the expected value Dr of the surface-to-surface distance between the red quantum dot 50r and the adjacent quantum dot 50 is expressed by following Expression (11):

$$\text{Dr} \text{=} \text{Brr} \times \text{Fr} \text{+} \text{Brg} \times \text{Fg} \text{+ Bbr} \times \text{Fb}$$

Likewise, the probability that the quantum dot 50 adjacent to the green quantum dot 50g is a red quantum dot 50r, the probability that the probability that the quantum dot 50 adjacent to the green quantum dot 50g is a green quantum dot 50g, and the probability that the quantum dot 50 adjacent to the green quantum dot 50g is a blue quantum dot 50b are also respectively Fr, Fg, and Fb; in addition, the probability that the quantum dot 50 adjacent to the blue quantum dot 50b is a red quantum dot 50r, the probability that the probability that the quantum dot 50 adjacent to the blue quantum dot 50b is a green quantum dot 50g, and the probability that the quantum dot 50 adjacent to the blue quantum dot 50b is a blue quantum dot 50b are also respectively Fr, Fg, and Fb. Accordingly, the expected value Dg of the surface-to-surface distance between the green quantum dot 50g and the adjacent quantum dot 50, and the expected value Db of the surface-to-surface distance between the blue quantum dot 50b and the adjacent quantum dot 50 are expressed by following Expression (12) and Expression (13):

$$\text{Dg} \text{=} \text{Brg} \times \text{Fr} \text{+} \text{Bgg} \times \text{Fg} \text{+ Bgb} \times \text{Fb}$$

and

$$\text{Db} \text{=} \text{Brb} \times \text{Fr} \text{+} \text{Bgb} \times \text{Fg} \text{+ Bbb} \times \text{Fb}$$

Foregoing Expressions (11), (12), and (13) are changed into following Expressions (14), (15), and (16) on the basis of the relationships expressed by Expressions (8), (9), and (10):

$$\text{Dr} \text{=} \text{} \text{Brr} / 2 + \left(\text{Brr} \times \text{Fr + Bgg} \times \text{Fg + Bbb} \times \text{Fb}\right) / 2$$

$$\text{Dg} \text{=} \text{} \text{Bgg} / 2 + \left(\text{Brr} \times \text{Fr + Bgg} \times \text{Fg + Bbb} \times \text{Fb}\right) / 2$$

and

$$\text{Db} \text{=} \text{} \text{Bbb} / 2 + \left(\text{Brr} \times \text{Fr + Bgg} \times \text{Fg + Bbb} \times \text{Fb}\right) / 2$$

From foregoing Expressions (14), (15), and (16), a relationship expressed by Expression (17) below is satisfied on the basis of the foregoing relationship expressed by Expression (6).

$$\text{Dr > Dg > Db}$$

That is, the expected value Dr of the surface-to-surface distance between the red quantum dot 50r and the adjacent quantum dot 50 is longer than the expected value Dg of the surface-to-surface distance between the green quantum dot 50g and the adjacent quantum dot 50, and the expected value Dg of the surface-to-surface distance between the green quantum dot 50g and the adjacent quantum dot 50 is longer than the expected value Db of the surface-to-surface distance between the blue quantum dot 50b and the adjacent quantum dot 50.

### Mobility

As earlier described, electrons including the quantum dots 50 within the light-emitting layer 43 move between the quantum dots 50 through hopping conduction, and their mobility depends on, as indicated by Expression (4) below, the surface-to-surface distance B between the quantum dots 50, the electron confinement factor a of the quantum dots 50, activation energy Ea, the Boltzmann constant kb, and temperature T.

$$\text{Mobility} ∝ \text{exp} \left(- 2 \text{aB} \text{−} \text{Ea} / \text{kbT}\right)$$

Here, the activation energy Ea is common between the red quantum dot 50r, the green quantum dot 50g and the blue quantum dot 50b, because the light-emitting layer 43 is applied with a uniform voltage. The temperature T is common, because the quantum dots 50 are contained in a single light-emitting layer43. The confinement factor a, which indicates a characteristic value based on the material of the quantum dots 50, stands at a common value. The Boltzmann constant kb, which is a chemical constant, stands at a common value.

In calculating the electron mobility of the red quantum dot 50r with the surface-to-surface distance B between the quantum dots 50, the expected value Dr of the surface-to-surface distance between the red quantum dot 50r and the adjacent quantum dot 50 can be used. Likewise, in calculating the electron mobility of the green quantum dot 50g, the expected value Dg of the surface-to-surface distance between the green quantum dot 50g and the adjacent quantum dot 50 can be used Likewise, in calculating the electron mobility of the blue quantum dot 50b, the expected value Db of the surface-to-surface distance between the blue quantum dot 50b and the adjacent quantum dot 50 can be used.

As such, based on the foregoing relationship expressed by Expression (17), the expected value Dr of the surface-to-surface distance between the red quantum dot 50r and the adjacent quantum dot 50 is the largest, and thus, the red quantum dot 50r has the smallest electron mobility. At the same time, the expected value Db of the surface-to-surface distance between the blue quantum dot 50b and the adjacent quantum dot 50 is the smallest, and thus, the blue quantum dot 50b has the largest electron mobility.

More generally speaking, the larger the light-emission wavelength of a quantum dot 50 is, the larger expected value the surface-to-surface distance between the quantum dot 50 and another quantum dot 50 adjacent thereto stands at. Hence, the electron mobility decreases exponentially along with increase in the surface-to-surface distance between the quantum dots 50, and thus, the larger the light-emission wavelength of the quantum dot 50 is, the smaller electron mobility the quantum dot 50 has.

### Electron Injection Efficiency

The efficiency of electron injection into the quantum dots 50 of each color depends of the product of the electron mobility of the quantum dots 50 of the color and the ease of electron injection into the unoccupied molecular orbitals of the quantum dots 50 of the color.

In this embodiment, the larger the light-emission wavelength of the quantum dot 50 is, the smaller electron mobility the quantum dot has, as earlier described. At the same time, the larger the light-emission wavelength of the quantum dot 50 is, the easier the electron injection into the quantum dot 50 is, because of a low LUMO. As a result, a decrease in electron injection efficiency resulting from the electron mobility can at least partly, preferably completely cancel out an increase in electron injection efficiency resulting from the ease of electron injection.

To be specific, with regard to the electron injection efficiency into the red quantum dots 50r, the influence of a relatively low degree of electron mobility of the red quantum dots 50r at least partly cancels out the influence of a relatively high degree of ease of electron injection of the red quantum dots 50r. Likewise, with regard to the efficiency of electron injection into the blue quantum dots 50b, the influence of a relatively high degree of electron mobility of the blue quantum dots 50b at least partly cancels out the influence of a relatively low degree of ease of electron injection of the blue quantum dots 50b. As such, the difference in the efficiency of electron injection into the quantum dots 50 according to this embodiment is smaller than the difference in the efficiency of electron injection into the quantum dots 150 in the comparative example shown in FIG. 3. It is preferable that a complete offset render the difference in the efficiency of electron injection according to this embodiment zero (0).

### Light Emission Efficiency

The light emission efficiency of the light-emitting elements ES (see FIG. 2) depends on the product of the light emission efficiency of the quantum dots 50, the efficiency of electron injection into the quantum dots 50, the efficiency of hole injection into the quantum dots 50, and the efficiency of taking out light to the outside of the light-emitting elements ES (i.e., the cathode 25). Among them, the light emission efficiency of the quantum dots 50 stands at a common value, because the ligands 52 that are more than adequate for avoiding deactivation of the quantum dots 50 modify the quantum dots 50. The efficiency of taking out light also stands at a common value, because the external structures of the light-emitting layers 43 are in common. The hole injection efficiency depends on the product of hole mobility and the ease of hole injection into the occupied orbitals of the quantum dots 50. The hole mobility depends on distance, like the electron mobility; for simplification of discussion, the influence of the hole mobility upon the light emission efficiency will not be addressed. The ease of hole injection stands at a common value, because the highest occupied molecular orbitals (HOMOs) are equal.

Accordingly, the light emission efficiency of each color component of the light-emitting element ES (see FIG. 2) depends on the efficiency of electron injection into the quantum dots 50 of the color. The difference in electron injection efficiency is small in this embodiment, as earlier described, thus enabling the difference in light emission efficiency between the individual color components to be reduced. This reduces the difference in light emission intensity between the individual color components to thus reduce color unevenness in light emitted from the light-emitting elements and to reduce a deviation of the light from white. Consequently, the configuration according to this embodiment facilitates achievement of the light-emitting elements ES that emit white light uniformly.

In contrast to this, the light-emitting elements containing the quantum dots 150 in the comparative example shown in FIG. 4 emit light that tends to produce color unevenness, and the colors of which tend to shift toward a short wavelength. Hence, color adjustment is difficult, thus making it difficult to obtain uniform white-light emission.

### Modification

### Configuration

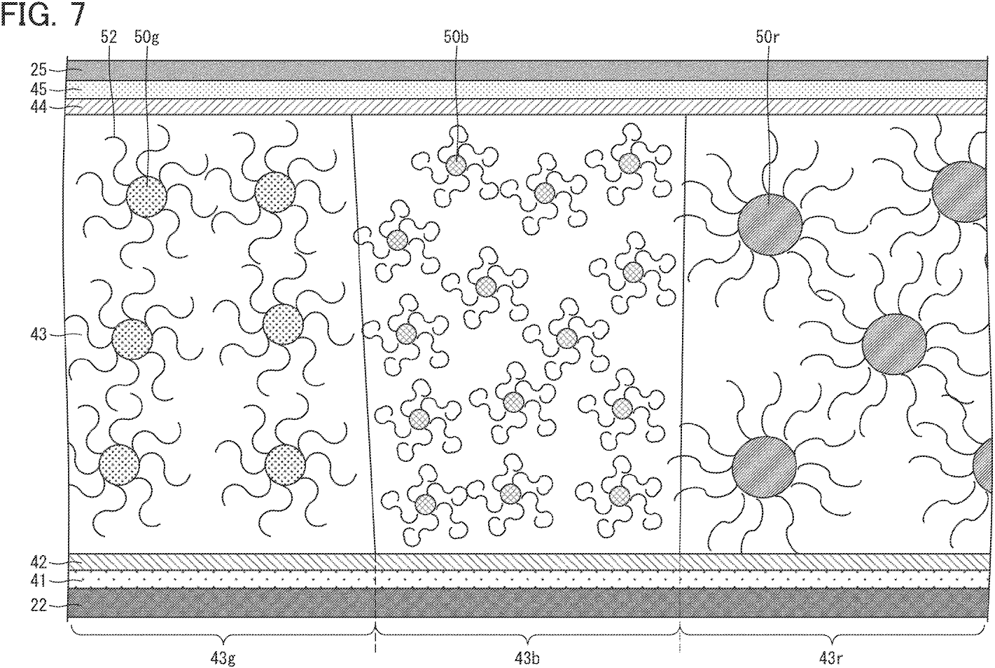

FIG. 7 is a schematic sectional view of the configuration in a modification of the light-emitting layer 43 shown in FIG. 5.

As illustrated in FIG. 7, the light-emitting layer 43 according to this modification includes the following: a red region 43r (first region) containing the red quantum dots 50r; a green region 43g (second region) containing the green quantum dots 50g; and a blue region 43b (third region) containing the blue quantum dots 50b. The red region 43r, the green region 43g, and the blue region 43b are arranged in parallel between the anode 22 and the cathode 25.

Each of the hole injection layer 41, hole transport layer 42, electron transport layer 44, and electron injection layer 45, when provided, is provided in common in the red region 43r, the green region 43g, and the blue region 43b.

The arrangement pattern of the red region 43r, green region 43g and blue region 43b may be any arrangement pattern in a plan view from a direction orthogonal to the anode 22 and cathode 25. Such a pattern may be an arrangement pattern where the red region 43r and the green region 43g are not adjacent to each other, an arrangement pattern where the red region 43r and the blue region 43b are not adjacent to each other, or an arrangement pattern where the green region 43g and the blue region 43b are not adjacent to each other. Each of the red region 43r, green region 43g and blue region 43b may be a single region or may be divided into a plurality of sub-regions.

### Formation Method

The light-emitting layer 43 in this modification is formed through process steps described below.

The first process step is putting the red quantum dots 50r having modified into a solution and stirring them to obtain a red dispersed solution with the red quantum dots 50r dispersed therein. Likewise, putting the green quantum dots 50g having modified into another solution and stirring them obtain a green dispersed solution with the green quantum dots 50g dispersed therein. Likewise, putting the blue quantum dots 50b having modified into another solution and stirring them obtain a blue dispersed solution with the blue quantum dots 50b dispersed therein. Accordingly, the red dispersed solution, the green dispersed solution, and the blue dispersed solution are individually prepared.

The next is applying the red dispersed solution, the green dispersed solution, and the blue dispersed solution sequentially or simultaneously onto the hole transport layer 42 (or the hole injection layer 41 or the anode 22) so as not to mix them to each other. Accordingly, the light-emitting layer 43 in this modification is separated into the red region 43r, the green region 43g, and the blue region 43b, as illustrated in FIG. 7.

### Surface-to-Surface Distance

A red quantum dot 50r in this modification is adjacent to at least a red quantum dot 50r. Likewise, a green quantum dot 50g in this modification is adjacent to at least a green quantum dot 50g, and a blue quantum dot 50b in this modification is adjacent to at least a blue quantum dot 50b. Accordingly, the foregoing relationship expressed by Expression (6) is satisfied.

$$\text{Brr > Bgg > Bbb}$$

Furthermore, the foregoing relationship expressed by Expression (7) can be satisfied when all three sets, i.e., a set of the red region 43r and green region 43g, a set of the red region 43r and blue region 43b, and a set of the green region 43g and blue region 43b, are in an arrangement pattern where they are adjacent to each other.

$$\text{Brg > Brb > Bgb}$$

However, one of ordinary skill in the art would understand that the foregoing relationship expressed by Expression (7) is not possibly satisfied when all the three sets are in such an adjacent arrangement pattern, because the red dispersed solution, the green dispersed solution, and the blue dispersed solution are prepared and applied individually. The foregoing relationship expressed by Expression (7) is not possibly satisfied when, for instance, there is a wall provided between the regions of the respective colors.

### Mobility

As earlier described, the electron mobility in the light-emitting layer 43 containing the quantum dots 50 is expressed by Expression (4) below.

$$\text{Mobility} ∝ \text{exp} \left(- 2 \text{aB} \text{−} \text{Ea} / \text{kbT}\right)$$

Electrons that move within the light-emitting layer 43 move substantially in the direction of an electric field applied to the light-emitting layer 43. It is hence less common that the electrons move across the boundary between the red region 43r and green region 43g, the boundary between the red region 43r and blue region 43b, and the boundary between the green region 43g and blue region 43b. The electrons can be thus assumed to move only inside the red region 43r, the green region 43g or the blue region 43b.

Base on this assumption, in calculating the electron mobility of the red quantum dots 50r with the surface-to-surface distance B between the quantum dots 50, the surface-to-surface distance Brr between the red quantum dots 50r can be used Likewise, in calculating the electron mobility of the green quantum dots 50g, the surface-to-surface distance Bgg between the green quantum dots 50g can be used. Likewise, in calculating the electron mobility of the blue quantum dots 50b, the surface-to-surface distance Bbb between the blue quantum dots 50b can be used.

As such, based on the foregoing relationship expressed by Expression (6), the surface-to-surface distance Brr between the red quantum dots 50r is the largest, and thus, the red quantum dots 50r have the smallest electron mobility. At the same time, the surface-to-surface distance Bbb between the blue quantum dots 50b is the smallest, and thus, the blue quantum dots 50b have the largest electron mobility.

It is noted that one of ordinary skill in the art would understand that even electrons that move across the boundaries in any arrangement pattern can offer a similar result (that is, the red quantum dots 50r have the smallest electron mobility, and the blue quantum dots 50b have the largest electron mobility), the details of which will be omitted due to complex description.

Consequently, the configuration according to this modification also facilitates achievement of the light-emitting elements ES that emit white light uniformly.

### Second Embodiment

The following details one embodiment of the present invention with reference to the drawings. It is noted that for convenience in description, components that have the same functions as components that have been described in the foregoing embodiment will be denoted by the same signs, and the description of them will not be repeated.

### Configuration

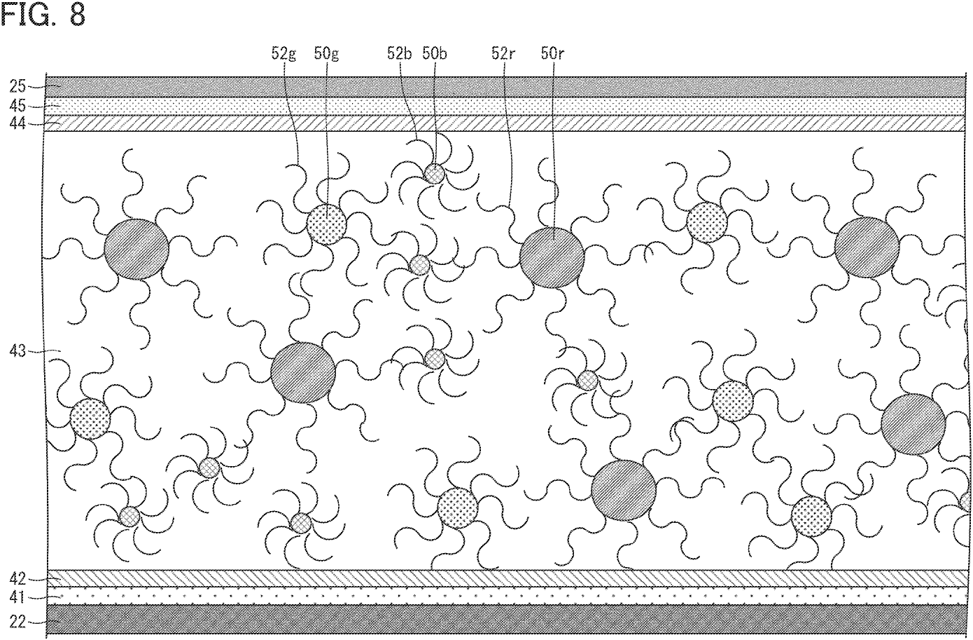

FIG. 8 is a schematic sectional view of the configuration of a light-emitting layer 43 according to this embodiment.

As illustrated in FIG. 8, the light-emitting layer 43 in this embodiment includes a plurality of red quantum dots 50r, a plurality of green quantum dots 50g, and a plurality of blue quantum dots 50b.

As illustrated in FIG. 8, each red quantum dot 50r is modified by a red ligand 52r (first ligand), each green quantum dot 50g is modified by a green ligand 52g (second ligand), and each blue quantum dot 50b is modified by a blue ligand 52b (third ligand).

The red ligand 52r, the green ligand 52g, and the blue ligand 52b are compounds different from each other. The molecular lengths of the respective red ligand 52r, green ligand 52g and blue ligand 52b satisfy a relationship expressed by Expression (18) below.

$$\begin{matrix}\text{The molecular length of the red ligand 52r > the molecular length of} \\ \text{the green ligand 52g > the molecular length of the blue ligand 52b}\end{matrix}$$

That is, the molecular length of the red ligand 52r is longer than the molecular length of the green ligand 52g, and the molecular length of the green ligand 52g is longer than the molecular length of the blue ligand 52b. The molecular lengths of the respective red ligand 52r, green ligand 52g and blue ligand 52b can be estimated by, for instance, identifying the structural formulas of compounds that are used for the respective ligands through a publicly known method.

For instance, the red ligand 52r, the green ligand 52g, and the blue ligand 52b have a linear alkyl group and an amine group and can satisfy a relationship expressed by Expression (19) below.

$$\begin{matrix}\text{The number of carbon atoms in the linear alkyl group of the red} \\ \text{ligand 52r > the number of carbon atoms in the linear alkyl group of} \\ \text{the green ligand 52g > the number of carbon atoms in the linear} \\ \text{alkyl group of the blue ligand 52b}\end{matrix}$$

That is, the carbon atoms in the linear alkyl group of the red ligand 52r outnumber the carbon atoms in the linear alkyl group of the green ligand 52g, and the carbon atoms in the linear alkyl group of the green ligand 52g outnumber the carbon atoms in the linear alkyl group of the blue ligand 52b.

The red ligand 52r, the green ligand 52g, and the blue ligand 52b function as an obstacle that physically hinders approaches of quantum dots 50 to each other, and this function enhances along with increase in the amount of each of the red ligand 52r, green ligand 52g and blue ligand 52b modifying a single quantum dot 50, and along with increase in the molecular lengths of the red ligands 52r, green ligands 52g and blue ligands 52b.

The amounts of the respective red ligand 52r, green ligand 52g and blue ligand 52b are more than adequate for avoiding deactivation of the quantum dots 50. Furthermore, the amounts of the respective red ligand 52r, green ligand 52g and blue ligand 52b may satisfy a relationship expressed by Expression (20) below.

$$\begin{matrix}\text{The amount of substance of the red ligand 52r modifying a single} \\ \text{red quantum dot 50r = the amount of substance of the green ligand} \\ \text{52g modifying a single green quantum dot 50g = the amount of} \\ \text{substace of the blue ligand 52b modifying a single blue quantum dot} \\ \text{50b}\end{matrix}$$

That is, the amount of substance of the red ligand 52r modifying a single red quantum dot 50r, the amount of substance of the green ligand 52g modifying a single green quantum dot 50g, and the amount of substance of the blue ligand 52b modifying a single blue quantum dot 50b may be equal to each other.

### Surface-to-Surface Distance and Electron Injection Efficiency

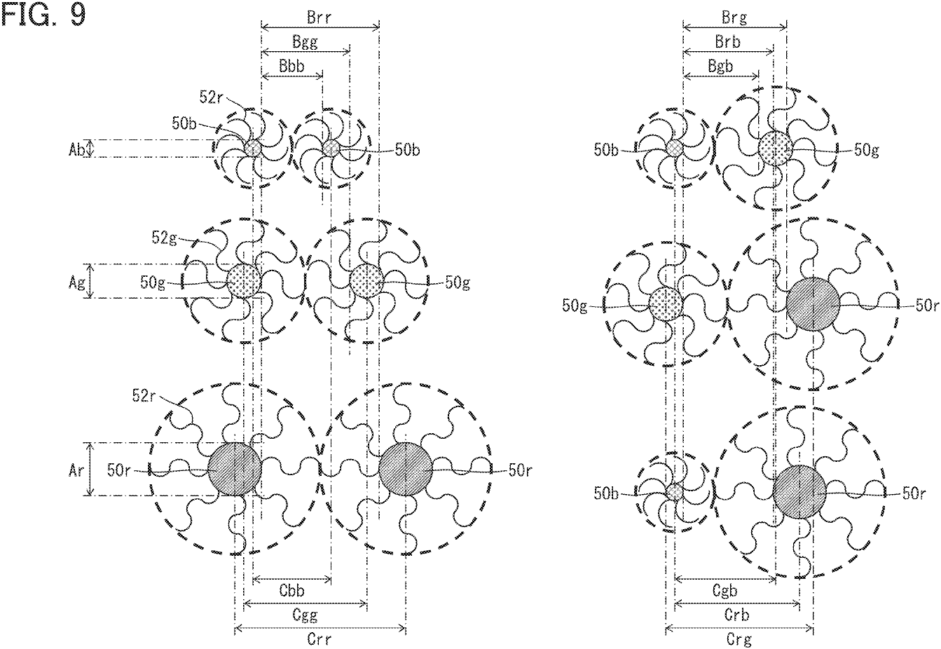

FIG. 9 is a schematic diagram illustrating surface-to-surface distances Brr, Bgg, Bbb, Brg, Bgb, and Brb between the quantum dots 50 contained in the light-emitting layer 43 shown in FIG. 8.

As earlier described, the function where ligands 52 physically hinder approaches of the quantum dots 50 to each other enhances along with increase in the molecular lengths of the red ligand 52r, green ligand 52g and blue ligand 52b. Accordingly, the foregoing relationship expressed by Expression (18) is satisfied, and as illustrated in FIG. 9, the foregoing relationships expressed by Expression (6) and Expression (7) are satisfied.

$$\text{Brr > Bgg > Bbb}$$

$$\text{Brg > Brb > Bgb}$$

As a result, like that in the first embodiment, the difference in the efficiency of electron injection into the quantum dots 50 according to this embodiment is smaller than the difference in the efficiency of electron injection into the quantum dots 150 in the comparative example shown in FIG. 3. It is preferable that the difference in the efficiency of electron injection according to this embodiment stand at zero (0).

Consequently, the configuration according to this embodiment also facilitates achievement of light-emitting elements ES that emit white light uniformly.

### First Modification

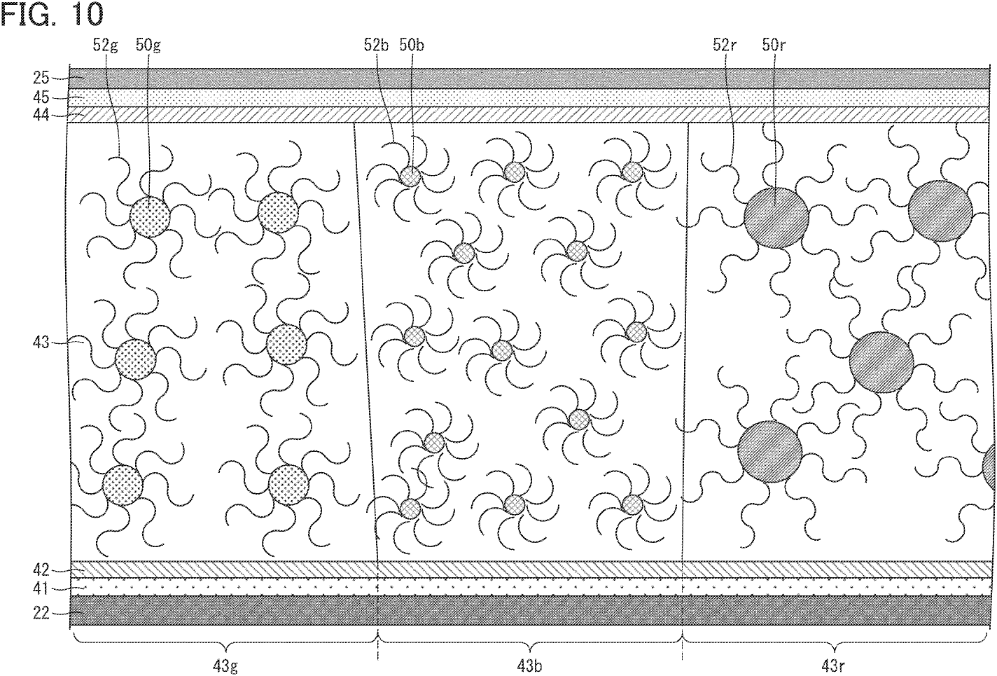

FIG. 10 is a schematic sectional view of the configuration in a modification of the light-emitting layer 43 shown in FIG. 8.

As illustrated in FIG. 10, the light-emitting layer 43 according to this modification includes a red region 43r containing the red quantum dots 50r, a green region 43g containing the green quantum dots 50g, and a blue region 43b containing the blue quantum dots 50b. The red region 43r, the green region 43g, and the blue region 43b are arranged in parallel between an anode 22 and a cathode 25.

Like the foregoing modification according to the first embodiment, this modification can obtain a result, that is, the red quantum dots 50r have the smallest electron mobility, and the blue quantum dots 50b have the largest electron mobility. Consequently, the configuration according to this modification also facilitates achievement of the light-emitting elements ES that emit white light uniformly.

### Second Modification

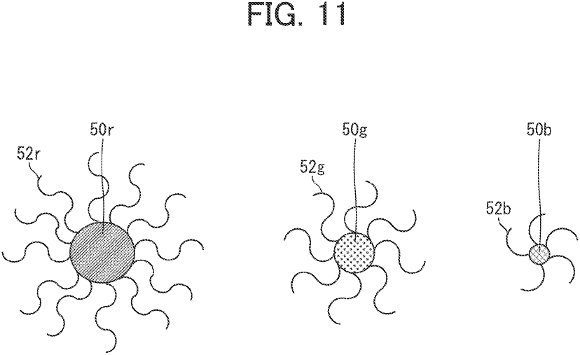

FIG. 11 is a schematic diagram of the configurations in modifications of the red ligand 52r, green ligand 52g and blue ligand 52b modifying the quantum dots contained in the light-emitting layer shown in FIG. 8.

As illustrated in FIG. 11, the foregoing configuration according to the first embodiment and the configuration according to this embodiment may be combined together to satisfy a relationship expressed by Expression (5)′, which is a modified version of foregoing Expression (5), instead of the foregoing relationship expressed by Expression (20). That is, both of the relationship expressed by Expression (5)′ below and the foregoing relationship expressed by Expression (18) may be satisfied.

$$\begin{matrix}\text{The amount of substance of the red ligand 52r modifying a single} \\ \text{red quantum dot 50r > the amount of substance of the green ligand} \\ \text{52g modifying a single green quantum dot 50g > the amount of} \\ \text{substance of the blue ligand 52b modifying a single blue quantum} \\ \text{dot 50b}\end{matrix}$$

$$\begin{matrix}\text{The molecular length of the red ligand 52r > the molecualr length of} \\ \text{the green ligand 52g > the molecular length of the vlue ligand 52b}\end{matrix}$$

That is, the amount of substance of the red ligand 52r modifying a single red quantum dot 50r is larger than the amount of substance of the green ligand 52g modifying a single green quantum dot 50g, and the amount of substance of the green ligand 52g modifying a single green quantum dot 50g is larger than the amount of substance of the blue ligand 52b modifying a single blue quantum dot 50b. In addition, the molecular length of the red ligand 52r is longer than the molecular length of the green ligand 52g, and the molecular length of the green ligand 52g is longer than the molecular length of the blue ligand 52b.

As earlier described, the function where the red ligand 52r, the green ligand 52g, and the blue ligand 52b physically hinder approaches of the quantum dots 50 to each other enhances along with increase in the amount of each of the red ligand 52r, green ligand 52g and blue ligand 52b modifying a single quantum dot 50, and along with increase in the molecular lengths of the red ligands 52r, green ligands 52g and blue ligands 52b.

Accordingly, both of the foregoing relationship expressed by Expression (5)′ and the foregoing relationship expressed by Expression (18) are satisfied, and thus, the foregoing relationships expressed by Expression (6) and Expression (7) are satisfied.

As such, a result can be obtained where the red quantum dots 50r have the smallest electron mobility, and where the blue quantum dots 50b have the largest electron mobility. Consequently, the configuration according to this modification also facilitates achievement of the light-emitting elements ES that emit white light uniformly.

### Summary

A light-emitting element according to a first aspect of the present invention includes the following: a first electrode; a second electrode; and a light-emitting layer provided between the first electrode and the second electrode, wherein the light-emitting layer contains a plurality of first quantum dots configured to emit light of a first color, a plurality of second quantum dots configured to emit light of a second color having a shorter wavelength than the light of the first color, and a plurality of third quantum dots configured to emit light of a third color having a shorter wavelength than the light of the second color, the surface-to-surface distance between the plurality of first quantum dots adjacent to each other is longer than the surface-to-surface distance between the plurality of second quantum dots adjacent to each other, and the surface-to-surface distance between the plurality of second quantum dots adjacent to each other is longer than the surface-to-surface distance between the plurality of third quantum dots adjacent to each other

The light-emitting element according to a second aspect of the present invention may be configured, in the light-emitting element according to the first aspect, such that the surface-to-surface distance between a first quantum dot and a second quantum dot adjacent to each other is longer than the surface-to-surface distance between the first quantum dot and a third quantum dot adjacent to each other, the first quantum dot belonging to the plurality of first quantum dots, the second quantum dot belonging to the plurality of second quantum dots, the third quantum dot belonging to the plurality of third quantum dots, and such that the surface-to-surface distance between the first quantum dot and the third quantum dot adjacent to each other is longer than the surface-to-surface distance between the second quantum dot and the third quantum dot.

A light-emitting element according to a third aspect of the present invention includes the following: a first electrode; a second electrode; and a light-emitting layer provided between the first electrode and the second electrode, wherein the light-emitting layer contains a plurality of first quantum dots configured to emit light of a first color, a plurality of second quantum dots configured to emit light of a second color having a shorter wavelength than the light of the first color, and a plurality of third quantum dots configured to emit light of a third color having a shorter wavelength than the light of the second color, the plurality of first quantum dots are each modified by a first ligand, the plurality of second quantum dots are each modified by a second ligand, the plurality of third quantum dots are each modified by a third ligand, the amount of substance of the first ligand modifying a single first quantum dot belonging to the plurality of first quantum dots is larger than the amount of substance of the second ligand modifying a single second quantum dot belonging to the plurality of second quantum dots, and the amount of substance of the second ligand modifying the single second quantum dot is larger than the amount of substance of the third ligand modifying a single third quantum dot belonging to the plurality of third quantum dots.

The light-emitting element according to a fourth aspect of the present invention may be configured, in the light-emitting element according to the third aspect, such that the first ligand, the second ligand, and the third ligand are identical compounds.

A light-emitting element according to a fifth aspect of the present invention includes the following: a first electrode; a second electrode; and a light-emitting layer provided between the first electrode and the second electrode, wherein the light-emitting layer contains a plurality of first quantum dots configured to emit light of a first color, a plurality of second quantum dots configured to emit light of a second color having a shorter wavelength than the light of the first color, and a plurality of third quantum dots configured to emit light of a third color having a shorter wavelength than the light of the second color, the plurality of first quantum dots are each modified by a first ligand, the plurality of second quantum dots are each modified by a second ligand, the plurality of third quantum dots are each modified by a third ligand, the molecular length of the first ligand is longer than the molecular length of the second ligand, and the molecular length of the second ligand is longer than the molecular length of the third ligand.

The light-emitting element according to a sixth aspect of the present invention may be configured, in the light-emitting element according to the fifth aspect, such that the first ligand, the second ligand, and the third ligand have a linear alkyl group and an amine group, carbon atoms in the linear alkyl group of the first ligand outnumber carbon atoms in the linear alkyl group of the second ligand, and the carbon atoms in the linear alkyl group of the second ligand outnumber carbon atoms in the linear alkyl group of the third ligand.

The light-emitting element according to a seventh aspect of the present invention may be configured, in the light-emitting element according to any one of the first and third to sixth aspects, such that the light-emitting layer is provided with a first region including the plurality of first quantum dots and configured to emit the light of the first color, a second region including the plurality of second quantum dots and configured to emit the light of the second color, and a third region including the plurality of third quantum dots and configured to emit the light of the third color.

The light-emitting element according to an eighth aspect of the present invention may be configured, in the light-emitting element according to the seventh, such that the first region, the second region, and the third region are arranged in parallel between the first electrode and the second electrode, and such that a common electric-charge transport layer is included in the first region, the second region, and the third region.

The light-emitting element according to a ninth aspect of the present invention may be configured, in the light-emitting element according to any one of the first to eighth aspects, such that each of the plurality of first quantum dots, each of the plurality of second quantum dots, and each of the plurality of third quantum dots contain at least one of CdS, CdSe, CdTe, ZnS, ZnSe, ZnTe, InN, InP, InAs, InSb, AlP, AlS, AlAs, AlSb, GaN, GaP, GaAs, GaSb, PbS, PbSe, Si, Ge, MgS, MgSe, and MgTe. Moreover, for a configuration in which two or more of them are included, the two or more may constitute a liquid-crystal system.

The light-emitting element according to a tenth aspect of the present invention may be configured, in the light-emitting element according to any one of the first to ninth aspects, such that the first color is red, the second color is green, the third color is blue, and the light-emitting element emits white light.

A display device according to an eleventh aspect of the present invention includes a plurality of the light-emitting elements according to any one of the first to tenth aspects.

The display device according to a twelfth aspect of the present invention may be configured, in the display device according to the eleventh aspect, such that a common electric-charge transport layer is included in the plurality of light-emitting elements.

The display device according to a thirteenth aspect of the present invention may be configured, in the display device according to the eleventh or twelfth aspect, such that each of the plurality of light-emitting elements includes a color filter of the first color, a color filter of the second color, and a color filter of the third color.

The display device according to a fourteenth aspect of the present invention may be configured, in the display device according to any one of the eleventh to thirteenth aspects, such that the first electrode is provided in an island form for each of the plurality of light-emitting elements, and such that the second electrode is provided in common in the plurality of light-emitting elements.

The display device according to a fifteenth aspect of the present invention may be configured, in the display device according to the fourteenth aspect, such that an edge cover film is formed so as to cover the edge of the first electrode.

The present invention is not limited to the foregoing embodiments. Various modifications can be devised within the scope of the claims. An embodiment that is obtained in combination, as appropriate, with the technical means disclosed in the respective embodiments is also included in the technical scope of the present invention. Furthermore, combining the technical means disclosed in the respective embodiments can form a new technical feature.

Reference Signs List

| | |
|---|---|
| 2 | display device |
| 22 | anode (first electrode) |
| 23 | edge cover (edge cover film) |
| 25 | cathode (second electrode) |
| 42 | hole transport layer (electric-charge transport layer) |
| 43 | light-emitting layer |
| 43 r | red region (first region) |
| 43 g | green region (second region) |
| 43 b | blue region (third region) |
| 44 | electron transport layer (electric-charge transport layer) |
| 50 r | red quantum dot (first quantum dot) |
| 50 g | green quantum dot (second quantum dot) |
| 50 b | blue quantum dot (third quantum dot) |
| 52 | ligand (first ligand, second ligand, third ligand) |
| 52 r | red ligand (first ligand) |
| 52 g | green ligand (second ligand) |
| 52 b | blue ligand (third ligand) |
| 54r, 54g, 54b | color filter |
| Brr, Bgg, Bbb, Brg, Brb, Bgb | surface-to-surface distance |
| ES | light-emitting element |

1. A light-emitting element comprising:
a first electrode;
a second electrode; and
a light-emitting layer provided between the first electrode and the second electrode,
wherein the light-emitting layer contains a plurality of first quantum dots configured to emit light of a first color, a plurality of second quantum dots configured to emit light of a second color having a shorter wavelength than the light of the first color, and a plurality of third quantum dots configured to emit light of a third color having a shorter wavelength than the light of the second color,
a surface-to-surface distance between first quantum dots adjacent to each other belonging to the plurality of first quantum dots is longer than a surface-to-surface distance between second quantum dots adjacent to each other belonging to the plurality of second quantum dots, and
the surface-to-surface distance between second quantum dots adjacent to each other belonging to the plurality of second quantum dots is longer than a surface-to-surface distance between third quantum dots adjacent to each other belonging to the plurality of third quantum dots, wherein
the light-emitting layer is provided with a first region including the plurality of first quantum dots and configured to emit the light of the first color, a second region including the plurality of second quantum dots and configured to emit the light of the second color, and a third region including the plurality of third quantum dots and configured to emit the light of the third color.

2. The light-emitting element according to claim 1, wherein
a surface-to-surface distance between a first quantum dot and a second quantum dot adjacent to each other is longer than a surface-to-surface distance between the first quantum dot and a third quantum dot adjacent to each other, the first quantum dot belonging to the plurality of first quantum dots, the second quantum dot belonging to the plurality of second quantum dots, the third quantum dot belonging to the plurality of third quantum dots, and
the surface-to-surface distance between the first quantum dot and the third quantum dot adjacent to each other is longer than a surface-to-surface distance between the second quantum dot and the third quantum dot.

3-7. (canceled)

8. The light-emitting element according to claim 1, wherein
the first region, the second region, and the third region are arranged in parallel between the first electrode and the second electrode, and
a common electric-charge transport layer is included in the first region, the second region, and the third region.

9-10. (canceled)

11. A display device comprising a plurality of the light-emitting elements according to claim 1.

12. The display device according to claim 11, wherein a common electric-charge transport layer is included in the plurality of light-emitting elements.

13. The display device according to claim 11, wherein each of the plurality of light-emitting elements includes a color filter of the first color, a color filter of the second color, and a color filter of the third color.

14. The display device according to claim 11, wherein
the first electrode is provided in an island form for each of the plurality of light-emitting elements, and
the second electrode is provided in common in the plurality of light-emitting elements.

15. The display device according to claim 14, wherein an edge cover film is formed so as to cover an edge of the first electrode.

16. A light-emitting element comprising:
a first electrode;
a second electrode; and
a light-emitting layer provided between the first electrode and the second electrode,
wherein the light-emitting layer contains a plurality of first quantum dots configured to emit light of a first color, a plurality of second quantum dots configured to emit light of a second color having a shorter wavelength than the light of the first color, and a plurality of third quantum dots configured to emit light of a third color having a shorter wavelength than the light of the second color,
the plurality of first quantum dots are each modified by a first ligand,
the plurality of second quantum dots are each modified by a second ligand,
the plurality of third quantum dots are each modified by a third ligand,
an amount of substance of the first ligand modifying a single first quantum dot belonging to the plurality of first quantum dots is larger than an amount of substance of the second ligand modifying a single second quantum dot belonging to the plurality of second quantum dots, and
the amount of substance of the second ligand modifying the single second quantum dot is larger than an amount of substance of the third ligand modifying a single third quantum dot belonging to the plurality of third quantum dots.

17. The light-emitting element according to claim 16, wherein the first ligand, the second ligand, and the third ligand are identical compounds.

18. The light-emitting element according to claim 16, wherein
the light-emitting layer is provided with a first region including the plurality of first quantum dots and configured to emit the light of the first color, a second region including the plurality of second quantum dots and configured to emit the light of the second color, and a third region including the plurality of third quantum dots and configured to emit the light of the third color.

19. The light-emitting element according to claim 18, wherein
the first region, the second region, and the third region are arranged in parallel between the first electrode and the second electrode, and
a common electric-charge transport layer is included in the first region, the second region, and the third region.

20. A display device comprising a plurality of the light-emitting elements according to claim 16.

21. The display device according to claim 20, wherein a common electric-charge transport layer is included in the plurality of light-emitting elements.

22. The display device according to claim 20, wherein each of the plurality of light-emitting elements includes a color filter of the first color, a color filter of the second color, and a color filter of the third color.

23. The display device according to claim 20, wherein
the first electrode is provided in an island form for each of the plurality of light-emitting elements, and
the second electrode is provided in common in the plurality of light-emitting elements.

24. The display device according to claim 23, wherein an edge cover film is formed so as to cover an edge of the first electrode.

25. A light-emitting element comprising:
a first electrode;
a second electrode and;
a light-emitting layer provided between the first electrode and the second electrode,
wherein the light-emitting layer contains a plurality of first quantum dots configured to emit light of a first color, a plurality of second quantum dots configured to emit light of a second color having a shorter wavelength than the light of the first color, and a plurality of third quantum dots configured to emit light of a third color having a shorter wavelength than the light of the second color,
the plurality of first quantum dots are each modified by a first ligand,
the plurality of second quantum dots are each modified by a second ligand,
the plurality of third quantum dots are each modified by a third ligand,
a molecular length of the first ligand is longer than a molecular length of the second ligand, and
the molecular length of the second ligand is longer than a molecular length of the third ligand, wherein
the light-emitting layer is provided with a first region including the plurality of first quantum dots and configured to emit the light of the first color, a second region including the plurality of second quantum dots and configured to emit the light of the second color, and a third region including the plurality of third quantum dots and configured to emit the light of the third color.

26. The light-emitting element according to claim 25, wherein
the first region, the second region, and the third region are arranged in parallel between the first electrode and the second electrode, and
a common electric-charge transport layer is included in the first region, the second region, and the third region.
